(19) United States
(12) Patent Application Publication
(10) Pub. No.: US 2008/0251124 A1
(43) Pub. Date: Oct. 16, 2008

(54) Solar Collectors Comprising a Cooling Machine

(75) Inventor: Jurgen Uehlin, Schopfheim (DE)

Correspondence Address: VOLPE AND KOENIG, P.C., UNITED PLAZA, SUITE 1600, 30 SOUTH 17TH STREET, PHILADELPHIA, PA, 19103, US

(73) Assignee: DURLUM-LEUCHTEN GMBH LICHTTECHNISCHE SPEZIALFABRIK, Schopfheim (DE)

(21) Appl. No.: 12/093,462

(22) PCT Filed: Nov. 14, 2006
(86) PCT No.: PCT/DE06/01990

§ 371 Date: May 13, 2008

(30) Foreign Application Priority Data
Nov. 15, 2005 (DE) 10 2005 054 364.2

(51) Int. Cl. H01L 31/00

(52) U.S. Cl. 136/259

(57) ABSTRACT

A method of generating energy from concentrated solar radiation by photovoltaic and thermally useable solar cells in which absorbed heat radiation heats the generator of an absorption cooling machine.

### BACKGROUND

The present invention relates to a solar collector with photovoltaic and thermally usable solar cells provided with at least one concentrating reflector.

Such photovoltaic modules serve to directly convert solar radiation into electric energy and/or heat.

The spectrum of electromagnetic radiation emitted by the sun can only be used to a limited extent for conversion into electricity because the voltaic-effective solar cells are only sensitive at a range from approximately 350 to 900 nm. The energy of UV-radiation below 350 nm and infrared radiation above 900 nm causes the cells to heat. Their effectiveness is maximized at temperatures of −20° C., and at or above 80° C. it is so low that the production of electricity is no longer profitable. When the temperatures are even higher, the cells may be damaged, with the values largely depending on the respective type of solar cells.

This problem drastically increases when the solar cells are operated with concentrated light. In case of a concentration factor above 10, on a clear summer's day just a few minutes are sufficient to reach temperatures that will have destructive effects. These cells must be effectively cooled.

In prior art, it is attempted to dissipate the heat either via large-area cooling elements or to connect the solar cells and/or their carriers with a cooling element having a refrigerant flowing trough it. It is also known to have a refrigerant flowing around the solar cells in order to improve the heat transfer, resulting in a multitude of problems with regard to corrosion and short circuit proofing and with a considerable amount of the electric energy generated by the cells being required for operating the circulating pump of the refrigerant.

### SUMMARY

The object of the invention is to provide a method that can be produced easily and at low costs and which improves the effectiveness of solar collector utilizing it.

The object is attained in claim 1 according to the invention. Additional features are described in the dependent claims.

The present invention allows the effective cooling of solar cells via an absorption refrigerator, with its operating energy being provided by the solar radiation not useable for photovoltaics.

The spectral separation of the collected radiation occurs preferably but not exclusively such that the flat photovoltaic cells are radiated as evenly as possible with the usable spectrum and the solar-thermal cells linearly with the separated portion of the radiation. The stronger the concentration of the thermal radiation, and accordingly narrower the thermally radiated area, the higher the temperature that can be reached. The generally known absorption refrigerating machines according to prior art predominantly operate either with the material pair ammonia/water at a generator temperature ranging from 80° C. to 250° C. and evaporating temperatures up to −70° C. or lithium bromide/water with a generator temperature ranging from 80° C. to 110° C. and evaporating temperatures up to 0° C. and absorption refrigerating machines with a material pair silica-gel/water at generator temperatures ranging from 60° C. to 95° C. The compressed refrigerant, e.g., ammonia, is evaporated from the solution in the generator by a driving temperature being supplied in the form of heat. The drive is therefore thermal and can occur in the thermal solar cells or by them. The heat radiation, which usually hinders the photovoltaic generation of electricity, can now be used to operate a refrigerating machine and utilizing the refrigeration enabled here to improve the effectiveness.

After having performed its work, the evaporated refrigerant must be condensed. According to the invention this process occurs primarily by open evaporation in coolable vessels, for example plates, tubes, or hoses, etc., which are at least partially formed and/or supported by the concentrators and/or solar cells and/or their carriers.

The separation of thermal and photovoltaic useable radiation is preferably caused by partially permeable spectral filters between the concentrator and the solar cell, which additionally has the beneficial effect that the photovoltaic cells remain relatively cool and the thermal radiation can be concentrated to the solar-thermal cells via optically effective means, such as lenses, mirrors, reflectors, etc.

Another method to keep undesired heat radiation from the solar cells is the spectral filtering of the impinging radiation using a transparent refrigerant, which moistens or flows around the cells at least in the radiated area, converts the radiation of no photovoltaic use into heat and transports it into a heat exchanger, which is at least partially cooled by evaporative heat loss. If the refrigerant is neither water nor a water-like substance, for example mono-propylene glycol or tri-propylene glycol, it must be guided in a closed vessel or circuit. If water is used as the filtration and heat-exchanging liquid it can be fed to an open evaporation after being charged with heat.

The heat loss by way of open evaporation is several times more effective than by convection or radiation.

When the reflector area is enlarged in order to increase the concentration factor, simultaneously the useable cooling area is enlarged as well. Due to the fact that the sensitive surfaces of the solar cells and/or the reflecting side of the concentrators are aligned towards the sun their back, being in the shade, can be used as the evaporation area or as a carrier of an evaporation device.

The medium to be evaporated is preferably water, beneficially in the form of rain water and/or tap water. Substances enhancing evaporation, such as a tenside, may be added thereto. The water supply occurs preferably via the capillary effect of porous materials, which for this purpose immerse in a liquid stored in a gutter, tub, or a similar collection vessel, which preferably is arranged below and/or above the evaporating device. Additionally or alternatively the evaporating devices can be sprayed with pressurized water supplied by a pump or the water line.

In order to increase the evaporation performance, the evaporation area can be formed by highly-porous materials having a large surface. Particularly suitable are felts, non-woven webs, fibrous mats, foams made from organic and/or inorganic materials, preferably metal foams, kilned earthenware, sintered elements, ceramic plates, and the like.

When evaporators are assembled parallel or slightly conically in reference to each other at a distance of few centimeters a chimney effect develops enhancing the cooling effect. In a recumbent arrangement of modules on an inclined area it is advantageous for a rear ventilation to be provided.

### BRIEF DESCRIPTION OF THE DRAWING

In the following the invention is explained in greater detail using a schematic representation of an exemplary embodiment.

Shown is:

FIG. 1 is a cross-sectional view through a solar collector according to the invention.

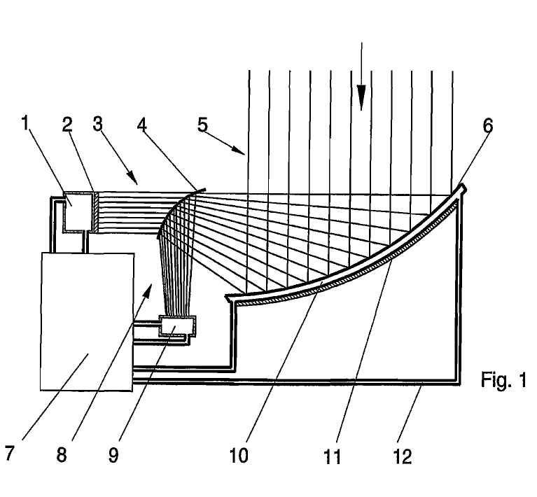

### DETAILED DESCRIPTION OF THE PREFERRED EMBODIMENT

The solar radiation 5 is deflected by the reflector 6 to the beam splitter 4, which separates the thermally useable frequencies 8 in the UV and infrared range and deflects them to the thermally effective solar cell 9, which directly or indirectly evaporates the coolant of the absorption refrigerating machine 7. The photovoltaic useable radiation 3 is converted into electricity by the solar cell 2, which is connected to the evaporator 1 of the refrigerating machine 7. The reflector 6 connected to the refrigerating machine 7 via the pipeline 12 is used as a condenser, with its cooling performance being increased by porous and/or large surfaces mounted at its rear and having a coating 11 of a preferably dark color, which is moistened by an easily evaporating liquid, preferably water. The cooling unit 1 can be connected via the pipeline 12 to the cooling chamber 10 of the reflector 6.

1. A method for cooling solar cells utilizing photovoltaics, radiated with concentrated solar light, comprising arranging at least one partially permeable spectral filter in a radiation path between a reflector and the solar cells, which separates radiation below 300 nm and above 900 nm and deflects the radiation below 300 nm and above 900 nm to a thermally usable solar collector, and heating a generator of an absorption refrigerating machine with the radiation below 300 nm and above 900 nm, and simultaneously using the reflector as a condenser for the refrigerating machine.

2. A method according to claim 1, further comprising cooling the reflector via open evaporation of cooling water.

3. A method according to claim 1, wherein the photovoltaic solar cells are connected to the evaporator of the refrigerating machine and effectively cooled.

4. A method according to claim 3, wherein the cooling is caused by open evaporation of water in a porous material.

5. A method according to claim 2, wherein the cooling is caused by the open evaporation of water in a porous material on a shaded side of a solar collector and/or concentrator of the solar cells.

6. A method according to claim 2, wherein the cooling water first moistens the photovoltaic solar cells at a radiated side and then is fed to an evaporating area.

7. A method according to claim 2, wherein the cooling water first flows around the photovoltaic solar cells and is then fed to an evaporating area.

8. A method according to claim 1, further comprising reducing a thermal load on the photovoltaic solar cells using the spectral filter.

9. A method according to claim 6, wherein the cooling water is supplied under pressure.

10. A method according to claim 6, wherein the cooling water is transported by capillary effects.

11. A method according to claim 2, wherein a cooling water reservoir is provided for the cooling water and comprises a self-filling rain water container.

12. A method according to claim 2, wherein the cooling is least two-tiered and comprises a closed primary circuit and open evaporation.

13. A method according to claim 12, wherein the refrigerant in the primary coolant circuit is not water or a water-like substance.

14. A method according to claim 12, wherein the refrigerant in the primary circuit is provided with spectral filter functions.
